(19) United States
(12) Patent Application Publication
(10) Pub. No.: US 2019/0058026 A1
(43) Pub. Date: Feb. 21, 2019

(54) ARRAY SUBSTRATE AND METHOD OF FABRICATING THE SAME

(71) Applicants: BOE TECHNOLOGY GROUP CO., LTD., Beijing (CN); HEFEI XINSHENG OPTOELECTRONICS TECHNOLOGY CO., LTD, Hefei, Anhui (CN)

(72) Inventors: Can YUAN, Beijing (CN); Yongqian LI, Beijing (CN); Pan XU, Beijing (CN); Chao JIAO, Beijing (CN)

(21) Appl. No.: 15/765,178

(22) PCT Filed: Jul. 7, 2017
(86) PCT No.: PCT/CN2017/092215

§ 371 Date: Mar. 30, 2018

(30) Foreign Application Priority Data
Nov. 11, 2016 (CN) 201621260766.4

(51) Int. Cl. H01L 27/32; H01L 27/12

(52) U.S. Cl. CPC H01L 27/3265; H01L 27/3262; H01L 27/1288; H01L 28/60; H01L 27/3248; H01L 27/1255; H01L 2227/323; H01L 27/1262

(57) ABSTRACT

The present application provides an array substrate, which includes a base substrate, and a first electrode, a first protection layer, a semiconductor electrode, a second protection layer and a second electrode formed sequentially on the base substrate. The second electrode and the semiconductor electrode constitute a storage capacitor, and the first electrode is below the semiconductor electrode to make the semiconductor electrode conductive. In a direction perpendicular to the base substrate, the thickness of at least a portion of the first protection layer in the first electrode area is less than that of other portions of the first protection layer outside the first electrode area, the first electrode area being an area defined by the projection of the first electrode on the first protection layer.

### TECHNICAL FIELD

The present disclosure relates to the field of display technology, and particularly, to an array substrate and a method of fabricating the same.

### BACKGROUND

In liquid crystal display panels and organic-light-emitting-diode (OLED) display panels, capacitors are properly designed for use in array circuits of array substrates. The most important use of the capacitors is to serve as storage capacitors for holding the source voltage during the current display process to the time at which the screen is updated. Typically, a semiconductor electrode and a second electrode constitute a storage capacitor, and a first electrode is configured to make the semiconductor electrode conductive to improve the ability of the storage capacitor to store and hold voltage.

### SUMMARY

The present disclosure provides an array substrate, including a base substrate, a first electrode on the base substrate, a first protection layer on the first electrode, a semiconductor electrode at a side of the first protection layer distal to the first electrode and whose projection on the base substrate at least partially overlaps a projection of the first electrode on the base substrate, a second protection layer at a side of the semiconductor electrode distal to the first protection layer, and a second electrode at a side of the second protection layer distal to the second protection layer and whose projection on the base substrate at least partially overlaps the projection of the semiconductor electrode on the base substrate. The first electrode is configured to make the semiconductor electrode conductive by applying a voltage signal. In a direction perpendicular to the base substrate, the thickness of at least a portion of the first protection layer in a first electrode area is less than that of other portions of the first protection layer outside the first electrode area, the first electrode area being an area defined by a projection of the first electrode on the first protection layer.

Optionally, the first protection layer in the first electrode area has a recess portion recessed towards the base substrate, and the semiconductor electrode has a portion within the recess portion.

Optionally, the recess portion has a width greater than or equal to that of the semiconductor electrode, such that the semiconductor electrode is disposed entirely within the recess portion.

Optionally, the array substrate further includes a third electrode at the side of the second protection layer distal to the base substrate and having a portion penetrating through the second protection layer to electrically connect with the semiconductor electrode.

Optionally, the array substrate further includes a third protection layer at a side of the second protection layer and the second electrode distal to the base substrate, and a fourth electrode at a side of the third protection layer distal to the base substrate and whose projection on the base substrate at least partially overlaps the projection of the second electrode on the base substrate. The fourth electrode has a portion penetrating through the third protection layer to electrically connect with the third electrode.

Optionally, the array substrate is an OLED substrate.

Optionally, the first electrode is a gate electrode, the second electrode and the third electrode are source electrodes, and the fourth electrode is an anode.

Optionally, the semiconductor electrode includes metal oxide, amorphous silicon or polysilicon.

The present disclosure further provides a display panel including the array substrate as described above.

The present disclosure further provides a method of fabricating an array substrate which is the above array substrate. The method includes: forming a pattern of the first electrode on the base substrate on a base substrate by using a single mask; forming, by using a single mask, a pattern of the first protection layer on the base substrate and the first electrode; forming, by using a single mask, the recess portion recessed towards the base substrate is formed on a surface of the first protection layer distal to the first electrode; forming a pattern of the semiconductor electrode at a side of the first protection layer distal to the first electrode, where the semiconductor electrode has a portion formed within the recess portion.

Optionally, the recess portion has a width greater than or equal to that of the semiconductor electrode, such that the semiconductor electrode is formed entirely within the recess portion.

Optionally, the step of forming the recess portion comprises: etching the side of the first protection layer distal to the base substrate to remove a portion of the first protection layer, so that the recess portion is formed.

Optionally, the array substrate further comprises a thin film transistor having a semiconductor layer, and the method further comprises:

forming the pattern of the semiconductor electrode and a pattern of the semiconductor layer by one patterning process.

### BRIEF DESCRIPTION OF DRAWINGS

FIG. 1 is a sectional view of an array substrate according to the existing techniques;

FIG. 2 is a sectional view of an array substrate according to an embodiment of the present application;

FIG. 3 is a sectional view of an array substrate according to another embodiment of the present application; and

FIG. 4 illustrates relationship between a voltage at a first electrode for making a semiconductor electrode conductive and a capacitance of a storage capacitor.

### DETAILED DESCRIPTION

To make those skilled in the art better understand the technical solutions of the present application, an array substrate according to the present application will be described in detail below in conjunction with the accompanying drawings.

In conventional array substrates, the distance between the first electrode and the semiconductor electrode is relatively large, which makes the storage capacitor less capable of storing and holding voltage, thereby adversely affecting the display of the display panel and resulting in dark-spot defects.

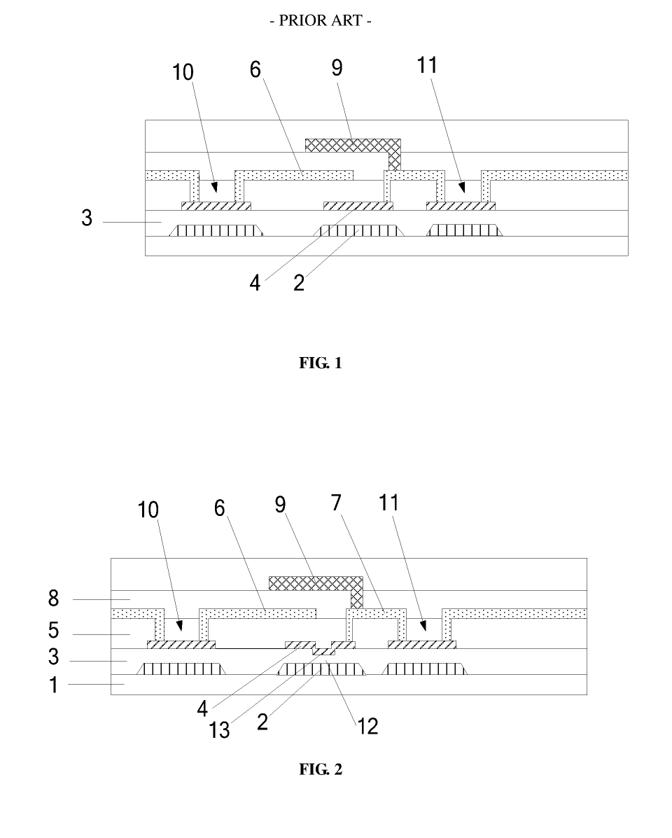

FIG. 1 illustrates a structure of an array substrate of a conventional OLED display panel. As illustrated in FIG. 1, a semiconductor electrode 4 and a second electrode 6 constitute a storage capacitor. During a display process, the storage capacitor is charged when a first driving transistor 10 is turned on, and meanwhile, a voltage at the second electrode 6 controls a second driving transistor 11 to turn on and thus controls a current flowing through a fourth electrode 9. When the first driving transistor 10 is turned off, the storage capacitor holds the current voltage at the second electrode 6 to maintain the on state of the second driving transistor 11, and thus the current flowing through the fourth electrode 9 is controlled to be constant. It is thus clear that the ability of the storage capacitor to hold voltage is important, which can directly affect normal display of the display panel. To improve performance of the storage capacitor, a first electrode 2 is below the semiconductor electrode 4 to make the semiconductor electrode 4 conductive, thereby improving the ability of the storage capacitor to store and hold voltage.

However, there is a first protection layer 3 between the first electrode 2 and the semiconductor electrode 4, and the first protection layer 3 also serves as an insulation layer between gates electrodes and active regions of the driving transistors 10 and 11. The first protection layer 3 is made thick to ensure the switching performance of the first and second transistors 10 and 11, so the effect of the first electrode 2 for making the semiconductor electrode 4 conductive is poor. Therefore, the storage capacitor has a poor ability to store and hold voltage, thereby adversely affecting the display of the display panel and resulting in dark-spot defects.

It has been found by the inventors that, in an array substrate of an OLED display panel, there is a particular relationship between a voltage at the first electrode for making the semiconductor electrode conductive and the capacitance of the storage capacitor. As illustrated in FIG. 4, when the voltage VDD applied to the first electrode 2 is increased from 4 volts (V) to 40V, the relationship between the scan voltage for the source electrode (i.e., the second electrode 6) of the first driving transistor 10 and the capacitance of the storage capacitor is as follows. The larger the voltage VDD applied to the first electrode 2, the lower the scan voltage at which the rising edge of the capacitance curve of the storage capacitor appears. That is to say, with a larger voltage at the first electrode 2, the capacitance of the storage capacitor can reach a predetermined value at a lower scan voltage for the second electrode 6. Therefore, the larger the voltage at the first electrode 2, the larger the electric field at the first electrode 2 and the stronger the storage ability of the storage capacitor.

In the technical solution of the present application, the electric field at the first electrode affects the storage ability of the storage capacitor more strongly by decreasing the distance between the semiconductor electrode and the first electrode.

Embodiments of the present application provide an array substrate. As illustrated in FIG. 2, the array substrate includes a base substrate 1, a first electrode 2 formed on the base substrate 1, a first protection layer 3 formed on the first electrode 2 distal to the base substrate 1, a semiconductor electrode 4 which is formed at a side of the first protection layer 3 distal to the first electrode 2 and whose projection on the base substrate 1 at least partially overlaps a projection of the first electrode 2 on the base substrate 1, a second protection layer 5 formed at a side of the semiconductor electrode 4 distal to the first protection layer 3, and a second electrode 6 which is formed at a side of the second protection layer 5 distal to the first protection layer 3 and whose projection on the base substrate 1 at least partially overlaps the projection of the semiconductor electrode 4 on the base substrate 1. In a direction perpendicular to the base substrate 1, the thickness of at least a portion of the first protection layer 3 in a first electrode area 12 is less than that of other portions of the first protection layer outside the first electrode area 12. The first electrode area 12 is an area defined by a projection of the first electrode 2 on the first protection layer 3.

In the array substrate according to the present application, the second electrode 2 and the semiconductor electrode 4 constitute a storage capacitor, and the first electrode 2 is below the semiconductor electrode 4 to make the semiconductor electrode 4 conductive by applying a voltage signal. In the direction perpendicular to the base substrate, the thickness of at least the portion of the first protection layer 3 in the first electrode area 12 is less than that of other portions of the first protection layer 3 outside the first electrode area 12, that is, a distance between the first electrode 2 and the semiconductor electrode 4 in the first electrode area 12 is less than a distance between the first electrode 2 and the semiconductor electrode 4 outside the first electrode area 12. Therefore, the electric field applied by the first electrode 2 affects the semiconductor electrode 4 more strongly and the semiconductor electrode 4 is made more conductive, thereby improving the ability of the storage capacitor to store and hold voltage without affecting the switching performance of the driving transistor and thus solving the problem that the display panel displays a dark spot.

Optionally, the semiconductor electrode 4 may be made of metal oxide, amorphous silicon or polysilicon. Specifically, the metal oxide includes an IGZO (Indium Gallium Zinc Oxide) semiconductor material.

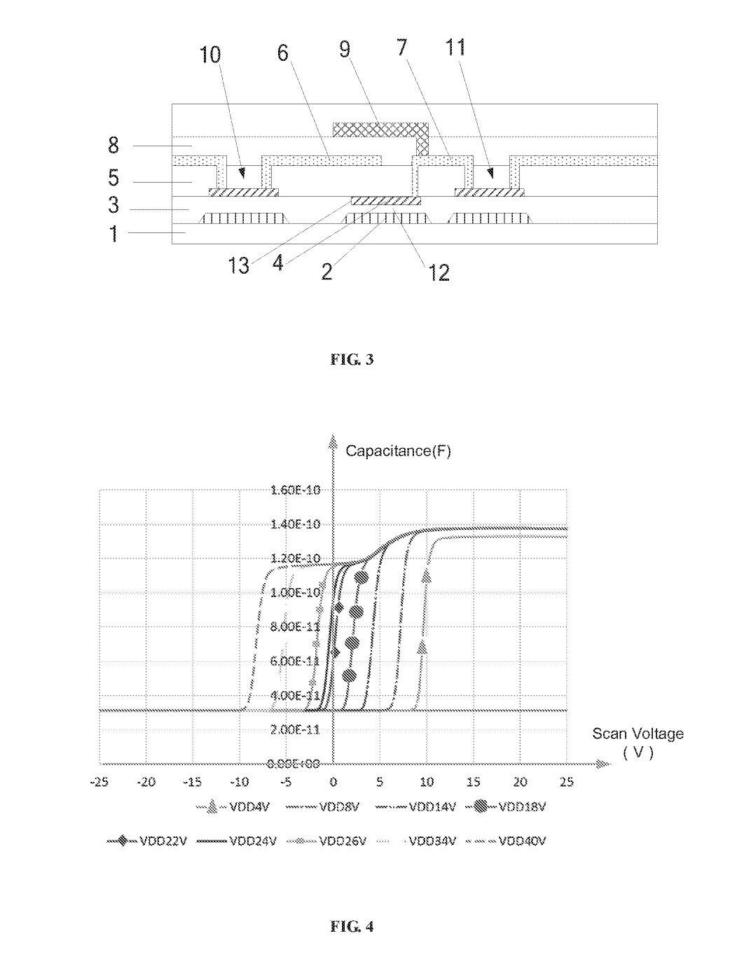

Next, the specific implement of the present embodiment will be described in detail in conjunction with FIGS. 2 and 3. As illustrated in FIG. 2, the first protection layer 3 in the first electrode area 12 has a recess portion 13, in which at least a portion of the semiconductor electrode 4 is accommodated. Specifically, first, the first electrode 2 is formed on the base substrate 1, and the first protection layer 3 is formed on the base substrate 1 and the first electrode 2. Then, a portion of the first protection layer 3 on an upper surface (namely, at a side of the first protection layer 3 distal to the base substrate 1) of the first protection layer 3 corresponding to the first electrode 2 is removed by an etching process with a mask having a pattern corresponding to the recess portion 13, so that the recess portion 13 recessed towards the base substrate is formed on the upper surface of the first protection layer 3. That is to say, only a portion of the first protection layer 3 in the first electrode area 12 is removed to form the recess portion 13, so that the portion of the first protection layer 3 in the first electrode area 12 has a decreased thickness while the thickness of the first protection layer 3 in the remaining area remains unchanged. Finally, the semiconductor electrode 4 is formed on the first protection layer 3 and the recess portion 13, where a portion of the semiconductor electrode 4 is accommodated in the recess portion 13, i.e., a lower surface of part of the semiconductor electrode 4 is in contact with a lower surface of the recess portion 13. By having the recess portion 13, the distance between the upper surface of the first electrode 2 and the lower surface of part of the semiconductor electrode 4 is decreased. Therefore, the electric field applied by the first electrode 2 affects part of the semiconductor electrode 4 more strongly, and the semiconductor electrode 4 is made more conductive.

Optionally, as illustrated in FIG. 3, the recess portion 13 has a width greater than or equal to that of the semiconductor electrode 4, such that the semiconductor electrode 4 is formed entirely within the recess portion 13. Specifically, the entire lower surface of the semiconductor electrode 4 is in contact with the lower surface of the recess portion 13, so the distance between the entire lower surface of the semiconductor electrode 4 and the upper surface of the first electrode 2 is decreased. Therefore, the electric field applied by the first electrode 2 affects the entire semiconductor electrode 4 more strongly, and the semiconductor electrode 4 is made further more conductive.

It should be noted that, a larger depth of the recess portion 13 indicates a smaller distance between the upper surface of the first electrode 2 and the lower surface of the semiconductor electrode 4, and thus the first electrode 2 affects the semiconductor electrode 4 more significantly and the semiconductor electrode 4 is made more conductive. However, a smaller distance between the upper surface of the first electrode 2 and the lower surface of the semiconductor electrode 4 also indicates a larger distance between the semiconductor electrode 4 and the second electrode 6, which adversely affects the capacitance of the storage capacitor formed by the semiconductor electrode 4 and the second electrode 6. Therefore, both the capacitance of the storage capacitor and the conductive effect of the semiconductor electrode 4 should be considered in the design of the array substrate, and as a result, the depth of the recess portion 13 will be determined according to actual situations.

As illustrated in FIGS. 2 and 3, the array substrate further includes a third electrode 7 formed at the side of the second protection layer 5 distal to the base substrate 1. The third electrode 7 has a portion penetrating through the second protection layer 5 to electrically connect with the semiconductor electrode 4. Specifically, the second electrode 6 is electrically connected with the first driving transistor 10 and the semiconductor electrode 4 is electrically connected with the second driving transistor 11 via the third electrode 7, so that the storage capacitor formed by the second electrode 6 and the semiconductor electrode 4 is connected to the circuit of the array substrate, thereby further increasing the ability of the storage capacitor to hold the voltage at the second electrode 6.

The array substrate further includes a third protection layer 8 formed at a side of the second protection layer 5 and the second electrode 6 distal to the base substrate 1, and a fourth electrode 9 which is formed at a side of the third protection layer 8 distal to the base substrate 1 and whose projection on the base substrate 1 at least partially overlaps a projection of the second electrode 6 on the base substrate 1. The fourth electrode 9 has a portion penetrating through the third protection layer 8 to electrically connect with the third electrode 7. Specifically, because of the fact that the projection of the fourth electrode 9 on the base substrate 1 partially overlaps the projection of the second electrode 6 on the base substrate 1, the storage capacitor consists of the second electrode 6, the fourth electrode 9 and the semiconductor electrode 4. In other words, the capacitance between the second electrode 6 and the semiconductor electrode 4 and the capacitance between the fourth electrode 9 and the second electrode 6 are included in the capacitance of the storage capacitor. Further, the fourth electrode 9 is connected with the semiconductor electrode 4 via the third electrode 7, so that the capacitor formed by the second electrode 6 and the semiconductor electrode 4 and the capacitor formed by the fourth electrode 9 and the second electrode 6 are connected in parallel. Therefore, the capacitance of the storage capacitor is a sum of the capacitance of the capacitor formed by the second electrode 6 and the semiconductor electrode 4 and the capacitance of the capacitor formed by the fourth electrode 9 and the second electrode 6, thereby further improving the ability of the storage capacitor to hold the voltage at the second electrode 6.

Optionally, the first electrode 2 is a gate electrode, the fourth electrode 9 is an anode, the second electrode 6 is a source electrode of the first driving transistor 10, and the third electrode 7 is a source electrode of the second driving transistor 11. For example, the first electrode 2 and gate electrodes of the first and second driving transistors 10 and 11 may have a same material.

The present application further provides a display panel including the array substrate described above. The display panel may be an OLED display panel or any other product or component having a display function and included in an electronic paper, a mobile phone, a tablet computer, a television, a digital album or the like.

It can be understood that the foregoing implementations are merely exemplary implementations used for describing the principle of the present disclosure, but the present disclosure is not limited thereto. Those ordinary skilled in the art may make various variations and improvements without departing from the spirit and essence of the present disclosure, and these variations and improvements shall fall into the protection scope of the present disclosure.

1-11. (canceled)

12. An array substrate, comprising:
a base substrate,
a first electrode on the base substrate,
a first protection layer on the first electrode distal to the base substrate,
a semiconductor electrode at a side of the first protection layer distal to the first electrode and whose projection on the base substrate at least partially overlaps a projection of the first electrode on the base substrate,
a second protection layer at a side of the semiconductor electrode distal to the first protection layer, and
a second electrode at a side of the second protection layer distal to the second protection layer and whose projection on the base substrate at least partially overlaps the projection of the semiconductor electrode on the base substrate,
wherein the first electrode is configured to make the semiconductor electrode conductive by applying a voltage signal, and in a direction perpendicular to the base substrate, a thickness of at least a portion of the first protection layer in a first electrode area is less than a thickness of other portions of the first protection layer outside the first electrode area, the first electrode area being an area defined by a projection of the first electrode on the first protection layer.

13. The array substrate of claim 12, wherein the first protection layer in the first electrode area has a recess portion recessed towards the base substrate, and the semiconductor electrode has a portion disposed within the recess portion.

14. The array substrate of claim 13, wherein the recess portion has a width greater than or equal to a width of the semiconductor electrode, such that the semiconductor electrode is disposed entirely within the recess portion.

15. The array substrate of claim 12, further comprising a third electrode at the side of the second protection layer distal to the base substrate and having a portion penetrating through the second protection layer to electrically connect with the semiconductor electrode.

16. The array substrate of claim 15, further comprising a third protection layer at a side of the second protection layer and the second electrode distal to the base substrate, and a fourth electrode at a side of the third protection layer distal to the base substrate and whose projection on the base substrate at least partially overlaps the projection of the second electrode on the base substrate, wherein the fourth electrode has a portion penetrating through the third protection layer to electrically connect with the third electrode.

17. The array substrate of claim 12, wherein the array substrate is an organic-light-emitting-diode substrate.

18. The array substrate of claim 12, wherein the first electrode is a gate electrode, the second electrode and the third electrode are source electrodes, and the fourth electrode is an anode.

19. The array substrate of claim 12, wherein the semiconductor electrode comprises metal oxide, amorphous silicon or polysilicon.

20. A display panel, comprising the array substrate of claim 12.

21. A method of fabricating an array substrate, comprising:
forming a pattern of a first electrode on a base substrate by using a single mask;
forming, by using a single mask, a pattern of a first protection layer on the first electrode distal to the base substrate;
forming, by using a single mask, a recess portion recessed towards the base substrate on a surface of the first protection layer distal to the first electrode; and
forming a pattern of a semiconductor electrode at a side of the first protection layer distal to the first electrode, wherein the semiconductor electrode has a portion formed within the recess portion.

22. The method of claim 21, wherein the recess portion has a width greater than or equal to a width of the semiconductor electrode, such that the semiconductor electrode is formed entirely within the recess portion.

23. The method of claim 21, wherein the step of forming the recess portion comprises:
etching the side of the first protection layer distal to the base substrate to remove a portion of the first protection layer, so that the recess portion is formed.

24. The method of claim 21, wherein the array substrate further comprises a thin film transistor having a semiconductor layer, and the method further comprises:
forming the pattern of the semiconductor electrode and a pattern of the semiconductor layer by one patterning process.
